(19) United States
(12) Patent Application Publication
(10) Pub. No.: US 2014/0226245 A1
(43) Pub. Date: Aug. 14, 2014

(54) CONTROL SYSTEM FOR SEMICONDUCTOR SWITCHES

(71) Applicant: ABB Oy, Helsinki (FI)

(72) Inventors: Markku TALJA, Jarvenpaa (FI); Jari Kankkunen, Helsinki (FI)

(73) Assignee: ABB Oy, Helsinki (FI)

(21) Appl. No.: 14/180,779

(22) Filed: Feb. 14, 2014

(30) Foreign Application Priority Data
Feb. 14, 2013 (FI) 20135135

(51) Int. Cl. H03K 17/081; H02H 9/02

(52) U.S. Cl. CPC H03K 17/081; H02H 9/02
USPC 361/93.9; 327/365

(57) ABSTRACT

A control system for semiconductor switches, the control system (CTRL) being configured to calculate an estimate of the instantaneous dissipation power of at least one semiconductor component unit (SU1) during an analysis period, whereby the at least one semiconductor component unit (SU1) includes at least one semiconductor switch (S1), and the instantaneous dissipation power includes the conduction losses and switching losses of the at least one semiconductor component unit (SU1).

### RELATED APPLICATION

This application claims priority under 35 U.S.C. §119 to Finnish Patent Application No. 20135135 filed in Finland on Feb. 14, 2013, the entire content of which is hereby incorporated by reference in its entirety.

### FIELD

The disclosure relates to a control system for semiconductor switches.

### BACKGROUND INFORMATION

It is known to protect semiconductor switches against overheating by using protection based on a thermal model, calculated over a time domain of, for example, approximately 0.5 ms. In a known semiconductor switch configuration, the temperature rise of a semiconductor component unit can be calculated on the basis of a thermal model by taking into account the temperature time constant of the semiconductor component unit, and by using a temperature sensor placed adjacent the semiconductor component unit.

Protection based on a thermal model does not detect a large switching frequency burst that high current creates.

### SUMMARY

A control system is disclosed for at least one semiconductor component including at least one semiconductor switch, the control system comprising: a processor configured to calculate an estimate of an instantaneous dissipation power of at least one semiconductor component unit during an analysis period, the instantaneous dissipation power including conduction losses and switching losses of the at least one semiconductor component unit.

A semiconductor switch configuration, comprising: at least one semiconductor component unit, the at least one semiconductor component unit including at least one semiconductor switch; and a processor configured to calculate an estimate of an instantaneous dissipation power of the at least one semiconductor component unit during an analysis period, the instantaneous dissipation power including conduction losses and switching losses of the at least one semiconductor component unit.

### BRIEF DESCRIPTION OF THE DRAWINGS

The disclosure is now described in greater detail in connection with the exemplary embodiments and with reference to the drawings, wherein:

FIG. 1 shows a semiconductor switch configuration including a control system according to an exemplary embodiment of the disclosure.

### DETAILED DESCRIPTION

The disclosure includes arranging a control system to calculate an estimate of the instantaneous dissipation power of a semiconductor component unit during an analysis period, the instantaneous dissipation power including the conduction losses and switching losses of the semiconductor component unit. At its shortest, the analysis period has, for example, the duration of one switching period of the semiconductor component unit, including the switching on and switching off of a semiconductor switch in the semiconductor component unit.

A control system according to exemplary embodiments of the disclosure can allow fast thermal protection of semiconductor component units.

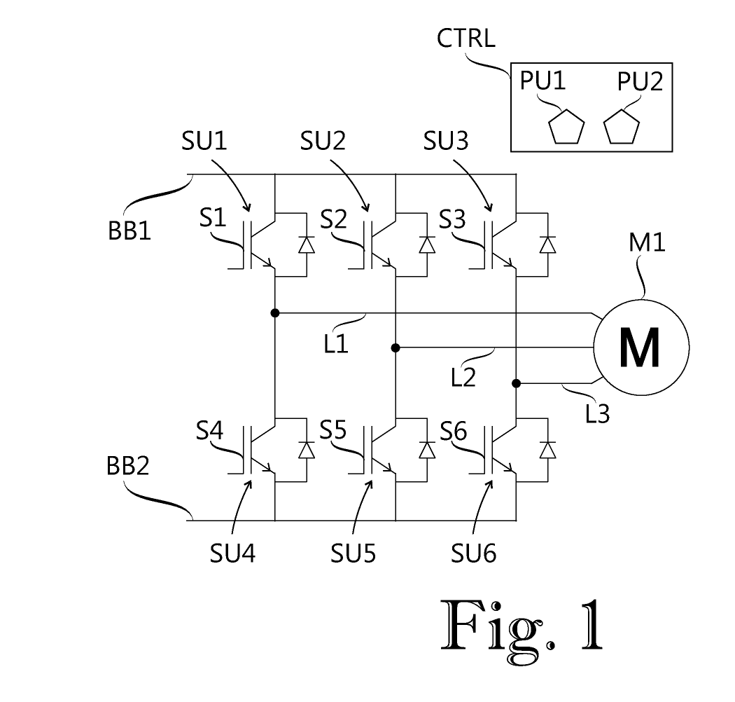

The semiconductor switch configuration of FIG. 1 includes six semiconductor component units SU1-SU6 and a control system CTRL. Each of the semiconductor component units SU1-SU6 includes a controllable semiconductor switch.

The semiconductor switches can be a series connected in pairs between a first input bus bar BB1 and a second input bus bar BB2, and arranged to invert the direct voltage between the first input bus bar BB1 and second input bus bar BB2 into three-phase alternating voltage which is applied to a motor M1 via output phases L1, L2, and L3. The output phase L1 is connected between the semiconductor switch S1 in the semiconductor component unit SU1 and the semiconductor switch S4 in the semiconductor component unit SU4. The output phase L2 is connected between the semiconductor switch S2 in the semiconductor component unit SU2 and the semiconductor switch S5 in the semiconductor component unit SU5. The output phase L3 is connected between the semiconductor switch S3 in the semiconductor component unit SU3 and the semiconductor switch S6 in the semiconductor component unit SU6.

The control system CTRL is configured and arranged to control the semiconductor switches S1-S6 in the semiconductor component units SU1-SU6. In addition, the control system CTRL is arranged to calculate an estimate of an instantaneous dissipation power of each semiconductor component unit SU1-SU6 during an analysis period, the instantaneous dissipation power including the conduction losses and switching losses. The minimum duration of the analysis period is one switching cycle, which begins at the switching on and ends at a subsequent switching off. In this context, instantaneous dissipation power refers to the average dissipation power over the analysis period. The control system CTRL uses this instantaneous dissipation power for fast protection of the semiconductor configuration, in other words, in a protection method where the analysis period is substantially shorter than in thermal model based protection.

The control system CTRL includes a real-time dissipation power calculator, where an instantaneous dissipation power of an analysis period is calculated by summing the instantaneous conduction loss power of the analysis period with the instantaneous switching loss power of the analysis period. The calculation of both the instantaneous conduction loss power and the instantaneous switching loss power utilizes information on the instantaneous value of the current, that is, the value of the current during the analysis period.

When one controllable semiconductor switch is examined, which is switched on infinitely fast at the beginning of an analysis period and switched off infinitely fast at the end of the analysis period, the instantaneous conduction loss power for the controllable semiconductor switch in question equals the product of the dropout voltage and instantaneous current. The instantaneous switching loss power of an analysis period is the energy that goes into the switching losses during the analysis period divided by the duration of the analysis period. The energy consumed on switching losses includes switching on energies and switching off energies.

The control system CTRL can be configured and arranged to carry out a first protective action as a response to the meeting of a first overload condition, the first overload condition including the detection of such a situation where the instantaneous dissipation power of at least one of the semiconductor component units SU1-SU6 exceeds a first threshold value during the analysis period. The first protective action includes limiting the switching frequency of the semiconductor switch in each semiconductor component unit where the instantaneous dissipation power exceeds the first threshold value during the analysis period.

The semiconductor component units SU1-SU6 can be identical to one another, so they all have the same first threshold value during the analysis period. In an exemplary embodiment according to the disclosure, the semiconductor switch configuration can include semiconductor component units that differ from one another and which have different first threshold values during the analysis period. The control system can be arranged to one where the semiconductor component unit specific first threshold values can be entered in the control system in connection with the initial settings.

The control system CTRL is additionally configured and arranged to carry out a second protective action as a response to the meeting of a second overload condition, the second overload condition including the detection of such a situation where the instantaneous dissipation power of at least one of the semiconductor component units

SU1-SU6 exceeds the first threshold value during the analysis period despite the use of the first protective action. The second protective action includes limiting the current of the semiconductor switch in each semiconductor component unit where the instantaneous dissipation power exceeds the first threshold value during the analysis period despite the first protective action being applied to the semiconductor component unit in question.

Furthermore, the control system CTRL is configured and arranged to carry out a third protective action as a response to the meeting of a third overload condition, the third overload condition including the detection of such a situation where the instantaneous dissipation power of at least one of the semiconductor component units SU1-SU6 exceeds the first threshold value during the analysis period despite the use of the second protective action. The third protective action includes the keeping of the semiconductor switch in non-conducting state in each semiconductor unit where the instantaneous dissipation power exceeds the first threshold value during the analysis period despite the use of the second protection method. The keeping of the semiconductor switch in the non-conducting state is continued until the predefined continuation conditions are met.

The control system CTRL can include a first processor unit PU1, which is configured to control the semiconductor switch in each semiconductor component unit, and a second processor unit PU2, which is configured to calculate an estimate for the instantaneous dissipation power of each semiconductor component unit during an analysis period. In such a case, the calculation of the dissipation power does not load the first processor unit PU1, in charge of controlling the semiconductor switches S1-S6 in the semiconductor component units SU1-SU6.

The second processor unit PU2 has available to it the details of the changes in state and instantaneous currents of the semiconductor switches S1-S6 in the semiconductor component units SU1-SU6. The control system CTRL is configured and arranged as one where the semiconductor component unit specific switching on and switching off energies can be entered to the second processor unit PU2 in connection with the initial settings. The dropout voltage curves of the semiconductor switches S1-S6 can be tabulated on the second processor unit PU2. The second processor unit can include, for example, an FPGA integrated circuit or an ASIC integrated circuit.

The control system according to an exemplary embodiment of the disclosure can be configured to calculate an estimate of the instantaneous dissipation power of one or more semiconductor component units during an analysis period. A semiconductor component unit can include one or more semiconductor switches.

In the exemplary embodiment shown in FIG. 1, each of the semiconductor component units SU1-SU6 can include an IGBT type of transistor, in which the actual semiconductor switch is connected antiparallel to the diode. The actual semiconductor switches can be marked with reference marks S1-S6 whereas no reference marks can be used to mark the diodes. In alternative exemplary embodiments, the semiconductor switch configuration according to an exemplary embodiment of disclosure can include other types of semiconductor switches, too.

The control system according to an exemplary embodiment of disclosure can be configured to utilize the calculation of instantaneous dissipation power for fast protection, and to utilize the prior art calculation, which is based on a thermal model, for longer-term protection.

Thus, it will be appreciated by those skilled in the art that the present invention can be embodied in other specific forms without departing from the spirit or essential characteristics thereof. The presently disclosed embodiments can be therefore considered in all respects to be illustrative and not restricted. The scope of the invention is indicated by the appended claims rather than the foregoing description and all changes that come within the meaning and range and equivalence thereof can be intended to be embraced therein.

What is claimed is:

1. A control system for at least one semiconductor component including at least one semiconductor switch, the control system comprising:
a processor configured to calculate an estimate of an instantaneous dissipation power of at least one semiconductor component unit during an analysis period, the instantaneous dissipation power including conduction losses and switching losses of the at least one semiconductor component unit.

2. A control system according to claim 1, comprising:
a first processor unit configured to control the switching on and switching off of the at least one semiconductor switch in the at least one semiconductor component unit; and
a second processor unit, configured to calculate the estimate for the instantaneous dissipation power of the at least one semiconductor component unit during the analysis period.

3. A control system according to claim 1, wherein the processor is configured to carry out a first protective action as a response to a first overload condition, the first overload condition including detection of such a situation where the instantaneous dissipation power of an analysis period for the at least one semiconductor component unit exceeds a first threshold value.

4. A control system according to claim 3, wherein the first protective action comprises:
limiting a switching frequency of the at least one semiconductor switch in the at least one semiconductor component unit whose instantaneous dissipation power of an analysis period exceeds the first threshold value.

5. A control system as claimed in claim 3, wherein the processor is configured to carry out a second protective action as a response to meeting of a second overload condition, the second protective action including limiting current of the at least one semiconductor switch in the at least one semiconductor component unit.

6. A control system according to claim 5, wherein the second overload condition includes detection of a situation where the instantaneous dissipation power of an analysis period for the at least one semiconductor component unit exceeds the first threshold value despite the use of the first protective action.

7. A control system as claimed in claim 5, wherein the processor is arranged to carry out a third protective action as a response to meeting of a third overload condition, the third protective action including the keeping of the at least one semiconductor switch in the at least one semiconductor component unit in a non-conducting state until predefined continuation terms are met.

8. A control system according to claim 7, wherein the third overload condition includes detection of a situation where the instantaneous dissipation power of an analysis period for the at least one semiconductor component unit exceeds the first threshold value despite the use of the second protective action.

9. A control system according to claim 1, wherein the analysis period is of the duration of a switching period of the semiconductor component unit, including a switching on and a switching off of the at last one semiconductor switch.

10. A semiconductor switch configuration, comprising:
at least one semiconductor component unit, the at least one semiconductor component unit including at least one semiconductor switch; and
a processor configured to calculate an estimate of an instantaneous dissipation power of the at least one semiconductor component unit during an analysis period, the instantaneous dissipation power including conduction losses and switching losses of the at least one semiconductor component unit.

11. A semiconductor switch configuration according to claim 10, comprising:
a first processor unit configured to control the switching on and switching off of the at least one semiconductor switch in the at least one semiconductor component unit; and
a second processor unit, configured to calculate the estimate for the instantaneous dissipation power of the at least one semiconductor component unit during the analysis period.

12. A semiconductor switch configuration according to claim 10, wherein the processor is configured to carry out a first protective action as a response to a first overload condition, the first overload condition including detection of such a situation where the instantaneous dissipation power of an analysis period for the at least one semiconductor component unit exceeds a first threshold value.

13. A semiconductor switch configuration according to claim 12, wherein the first protective action comprises:
limiting a switching frequency of the at least one semiconductor switch in the at least one semiconductor component unit whose instantaneous dissipation power of an analysis period exceeds the first threshold value.

14. A semiconductor switch configuration as claimed in claim 12, wherein the processor is configured to carry out a second protective action as a response to meeting of a second overload condition, the second protective action including limiting current of the at least one semiconductor switch in the at least one semiconductor component unit.

15. A semiconductor switch configuration according to claim 14, wherein the second overload condition includes detection of a situation where the instantaneous dissipation power of an analysis period for the at least one semiconductor component unit exceeds the first threshold value despite the use of the first protective action.

16. A semiconductor switch as claimed in claim 14, wherein the processor is configured to carry out a third protective action as a response to meeting of a third overload condition, the third protective action including the keeping of the at least one semiconductor switch in the at least one semiconductor component unit in a non-conducting state until predefined continuation terms are met.

17. A semiconductor switch according to claim 16, wherein the third overload condition includes detection of a situation where the instantaneous dissipation power of an analysis period for the at least one semiconductor component unit exceeds the first threshold value despite the use of the second protective action.

18. A semiconductor switch according to claim 10, wherein the analysis period is of the duration of a switching period of the semiconductor component unit, including a switching on and a switching off of the at last one semiconductor switch.
